(19) United States
(12) Patent Application Publication
(10) Pub. No.: US 2026/0231341 A1
(43) Pub. Date: Aug. 6, 2026

(54) WIRE HARNESS

(71) Applicant: Yazaki Corporation, Tokyo (JP)

(72) Inventors: Katsunori SATO, Shizuoka (JP); Tatsuya OGA, Shizuoka (JP)

(73) Assignee: Yazaki Corporation, Tokyo (JP)

(21) Appl. No.: 19/650,472

(22) Filed: Apr. 17, 2026

Related U.S. Application Data
(63) Continuation of application No. PCT/JP2025/004307, filed on Feb. 10, 2025.

(30) Foreign Application Priority Data
Mar. 14, 2024 (JP) 2024-039862

(51) Int. Cl. H05K 5/00; H05K 5/02

(52) U.S. Cl. CPC H05K 5/0047; H05K 5/0226

(57) ABSTRACT

A wire harness includes: a flat wiring member formed in a U shape, the flat wiring member including a first portion, a second portion, and an intermediate portion connecting the first portion and the second portion; a first case that holds the first portion; a second case that holds the second portion; and a coupling portion. The first case includes a first support wall. The second case includes a second support wall. The coupling portion is configured to couple the first case and the second case to each other in a state where the first support wall and the second support wall are aligned in a width direction. The coupling portion includes a hinge portion capable of rotating the first case and the second case relative to each other to make the first support wall and the second support wall face each other.

### CROSS-REFERENCE TO RELATED APPLICATION(S

This application is a continuation application of International Application PCT/JP2025/004307, filed on February 10, 2025 which claims the benefit of priority from Japanese Patent Application No. 2024-039862 filed on March 14, 2024 and designating the U.S., the entire contents of which are incorporated herein by reference.

### BACKGROUND OF THE INVENTION

### 1. Field of the Invention

The present invention relates to a wire harness.

### 2. Description of the Related Art

There are conventionally known flat wiring members such as a flexible printed circuit board. Japanese Patent Application Laid-open No. 2015-170699 discloses a flexible printed circuit board capable of easily implementing elongated wire arrangement. The flexible printed circuit board of Japanese Patent Application Laid-open No. 2015-170699 includes: a first band-shaped member and a second band-shaped member each having a conductive portion and an insulating portion covering the conductive portion; and a first coupling member that couples a first end of the first band-shaped member and a first end of the second band-shaped member to each other.

Here, there has been a study of accommodating one part of a long flat wiring member in a first case and accommodating another part in a second case. When accommodating one flat wiring member in two cases, the load on the flat wiring member when handling the cases can desirably be reduced. For example, when the two cases move independently without being coupled to each other, a large load is sometimes applied to the flat wiring member.

### SUMMARY OF THE INVENTION

An object of the present invention is to provide a wire harness capable of reducing the load on a flat wiring member when handling a case.

To achieve the above-described objective, a wire harness according to one aspect of the present invention includes a flat wiring member formed in a U shape, the flat wiring member including a first portion having a straight line shape, a second portion having a straight line shape, and an intermediate portion connecting an end of the first portion and an end of the second portion; a first case that holds the first portion; a second case that holds the second portion; and a coupling portion that couples the first case and the second case to each other, wherein the first case includes a first support wall that supports the first portion, the second case includes a second support wall that supports the second portion, the coupling portion is configured to couple the first case and the second case to each other in a state where the first support wall and the second support wall are aligned in a width direction of the flat wiring member, and the coupling portion includes a hinge portion capable of rotating the first case and the second case relative to each other to make the first support wall and the second support wall face each other.

According to another aspect of the present invention, in the wire harness, it is preferable that the second case includes: a main body having the second support wall; and a cover that engages with the main body and covers the second support wall, and the coupling portion is connected to the cover, and is coupled to the first case in a state where the cover is engaged with the main body.

According to still another aspect of the present invention, it is preferable that the wire harness further includes a rotating structure that couples the first case and the second case to each other so as to be rotatable relative to each other, wherein the rotating structure couples the first case and the second case to each other in a state where the first case and the second case are overlapped with each other with the first support wall and the second support wall facing each other, and the rotating structure is configured to be able to rotate the first case and the second case relative to each other such that the first support wall and the second support wall are aligned in a straight line shape.

### BRIEF DESCRIPTION OF THE DRAWINGS

FIG. 1 is a perspective view of a wire harness according to an embodiment;

FIG. 2 is a perspective view of the wire harness according to the embodiment;

FIG. 3 is a plan view of a case according to the embodiment;

FIG. 4 is a perspective view of the case according to the embodiment;

FIG. 5 is a plan view of a flat wiring member according to the embodiment;

FIG. 6 is a plan view of the wire harness according to the embodiment;

FIG. 7 is a perspective view of the wire harness according to the embodiment;

FIG. 8 is a perspective view of the wire harness according to the embodiment;

FIG. 9 is a perspective view of the wire harness according to the embodiment;

FIG. 10 is a diagram illustrating a second rotation process of the embodiment;

FIG. 11 is a perspective view of the wire harness according to the embodiment; and

FIG. 12 is a perspective view of the flat wiring member according to the embodiment.

### DETAILED DESCRIPTION OF THE PREFERRED EMBODIMENTS

Hereinafter, a wire harness according to an embodiment of the present invention will be described in detail with reference to the drawings. Note that the present invention is not limited by the embodiment. Moreover, components in the following embodiment include those that are easily conceivable for those skilled in the art or substantially identical.

### Embodiment

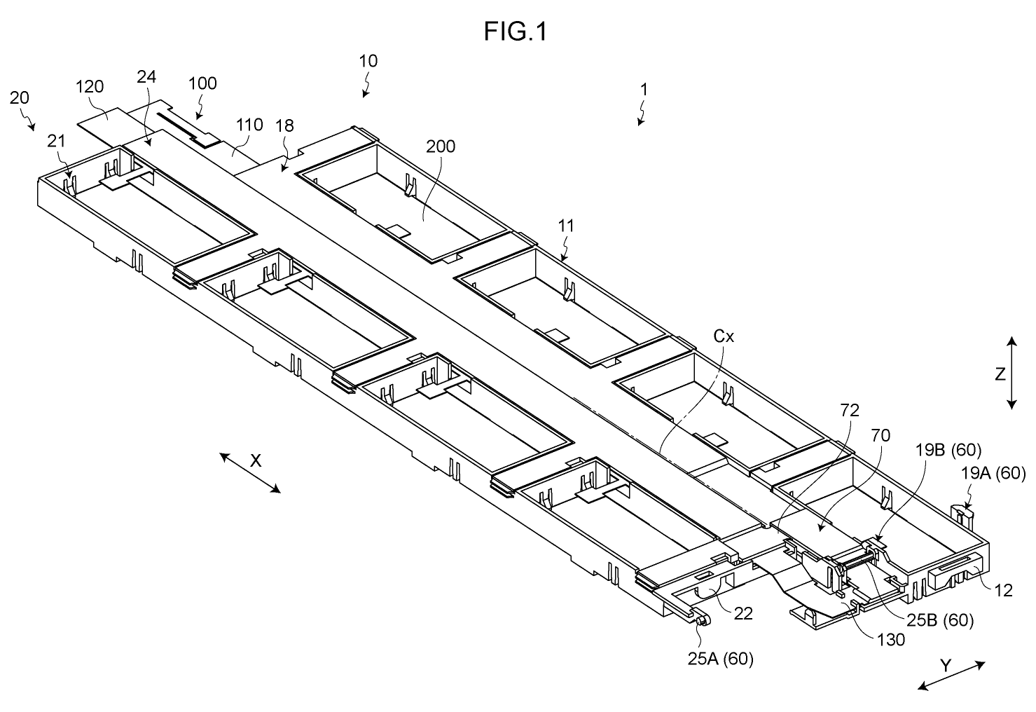

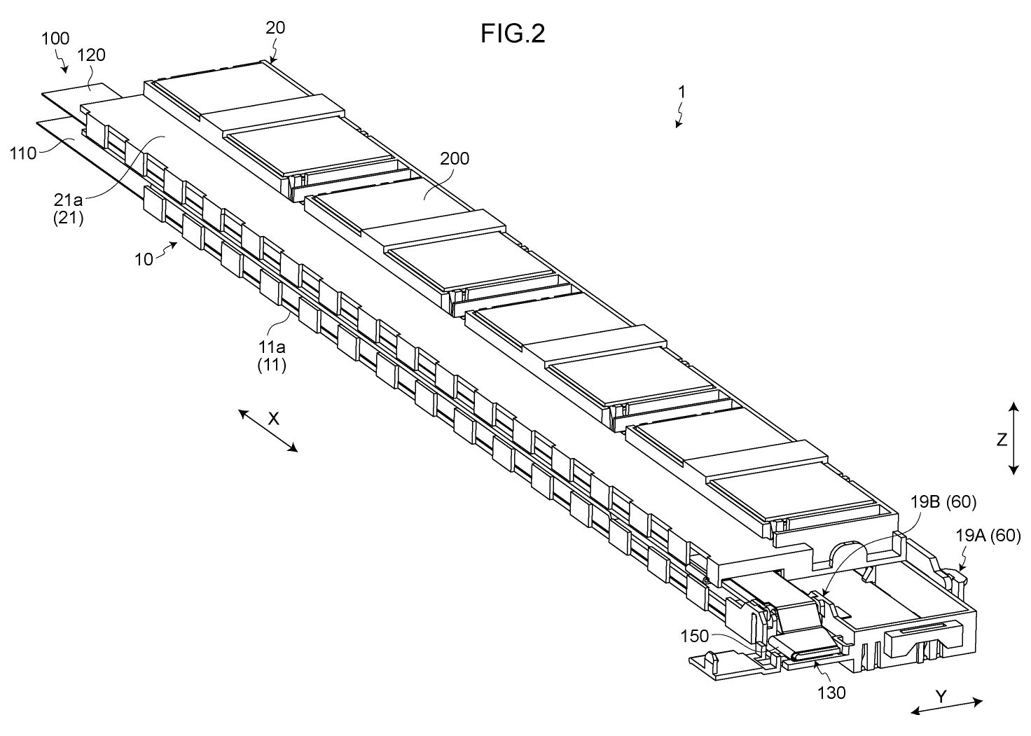

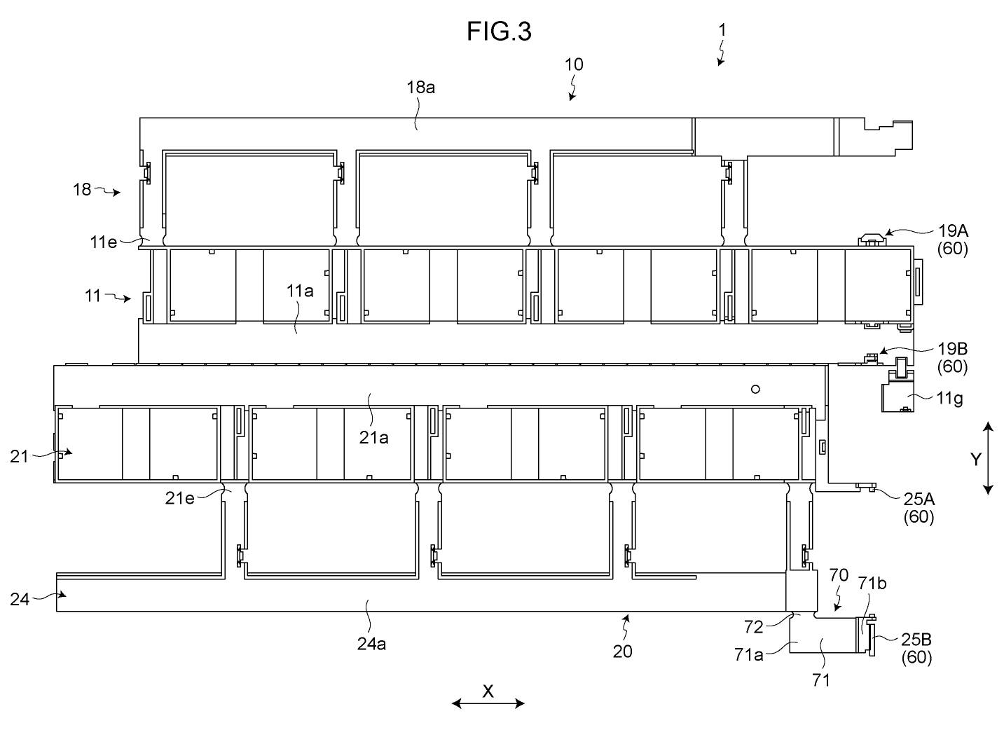

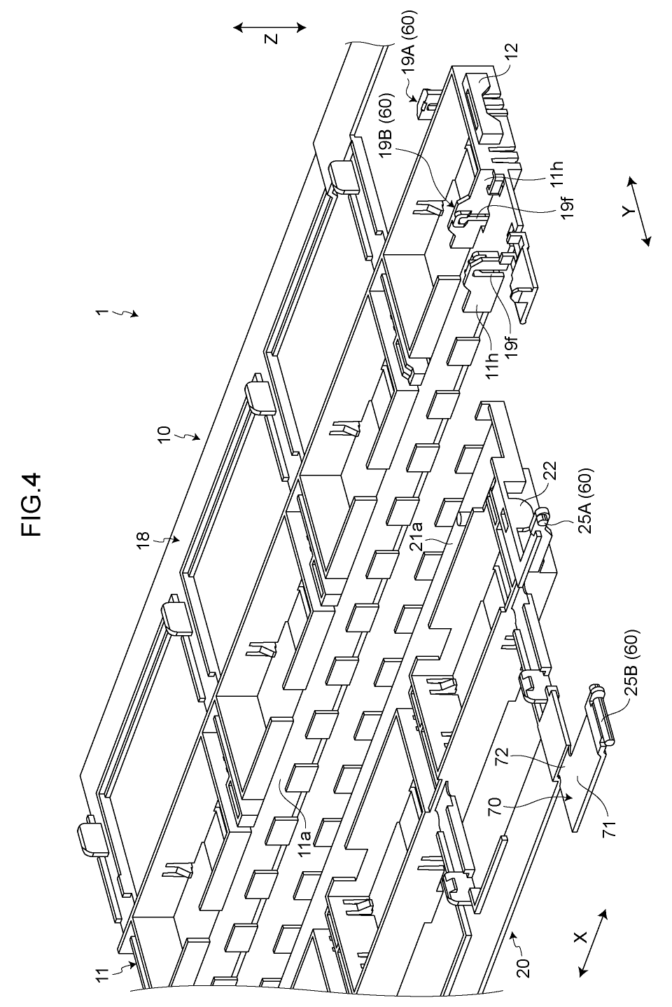

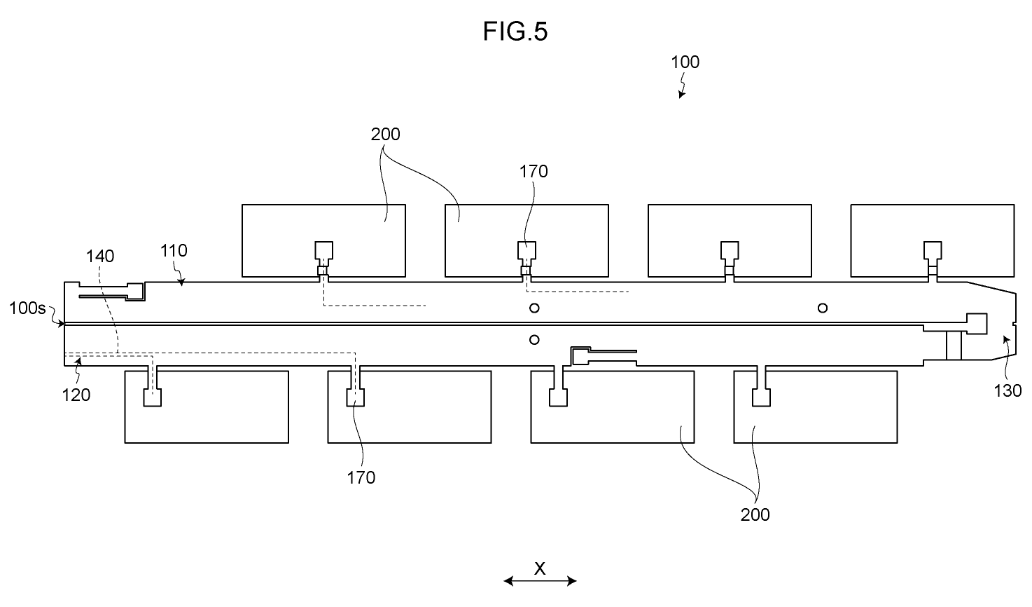

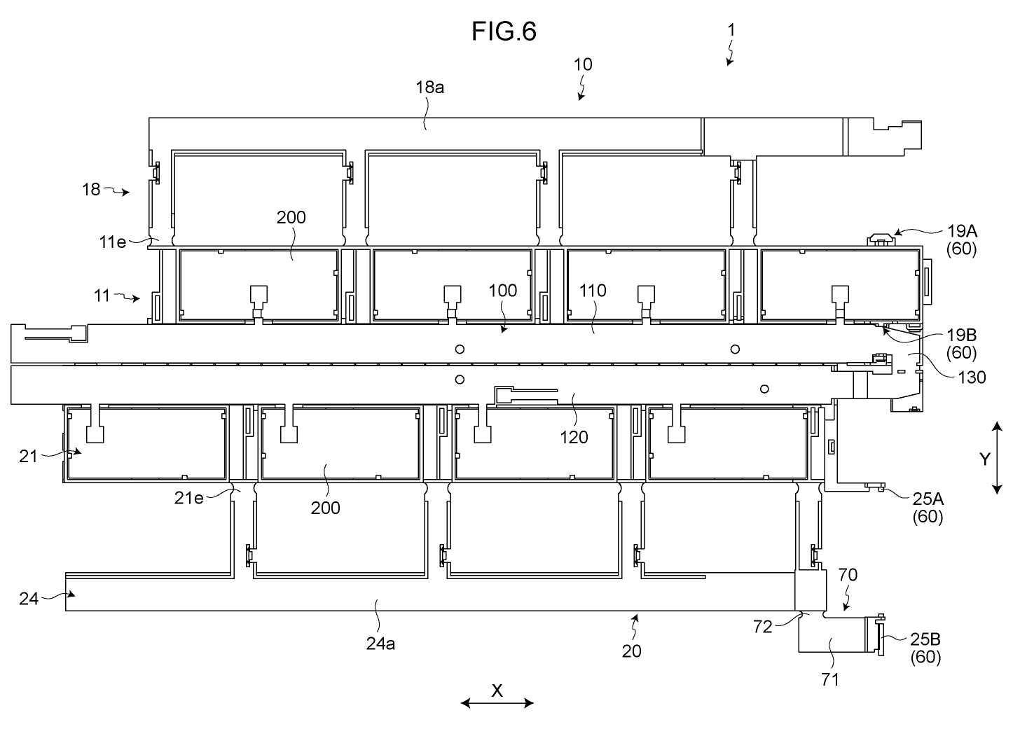

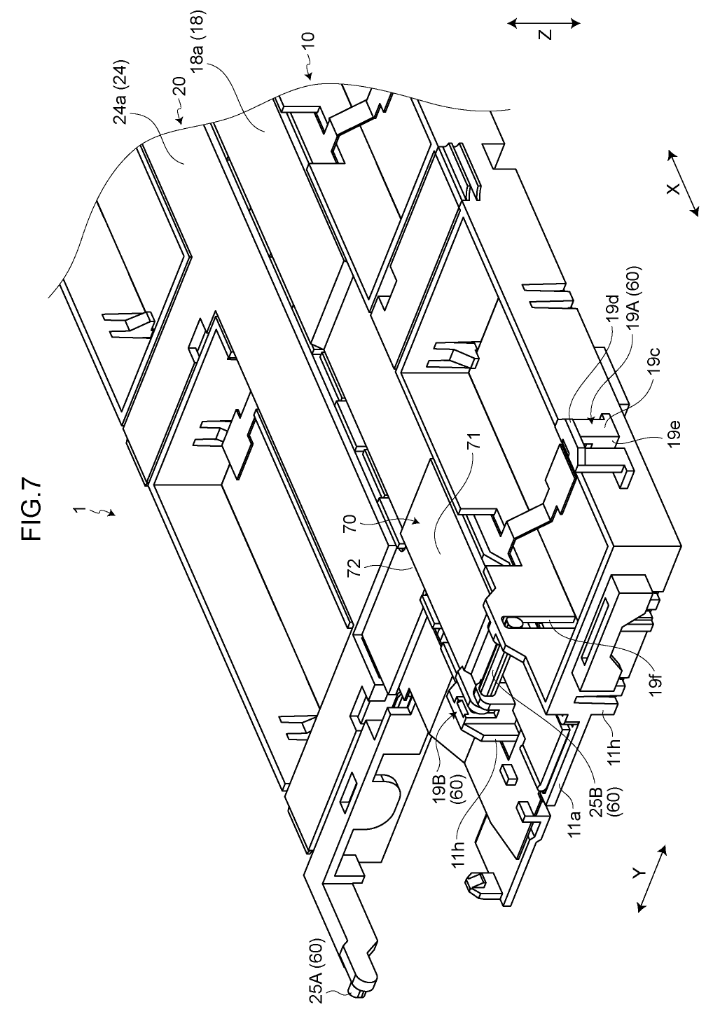

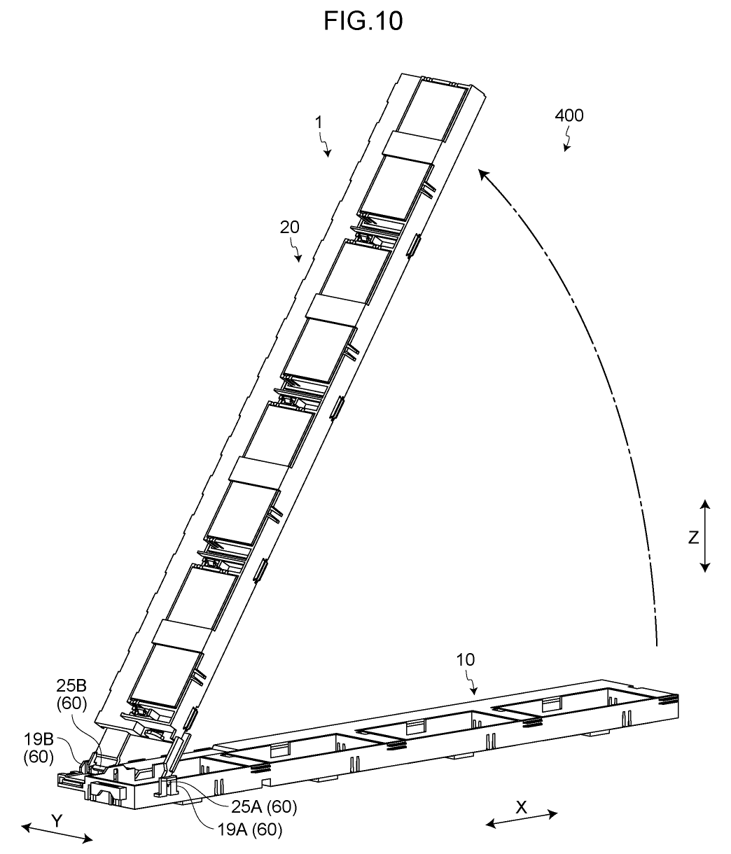

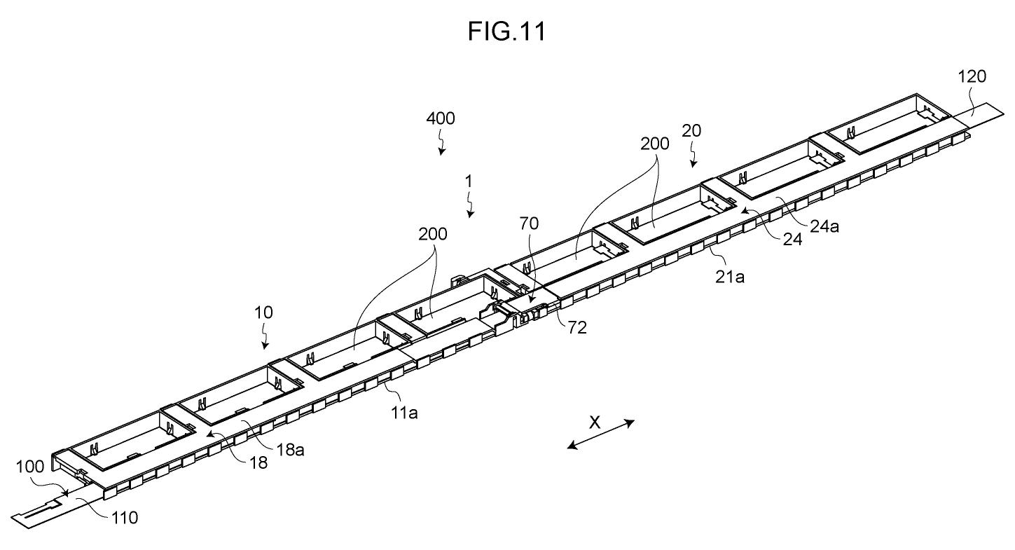

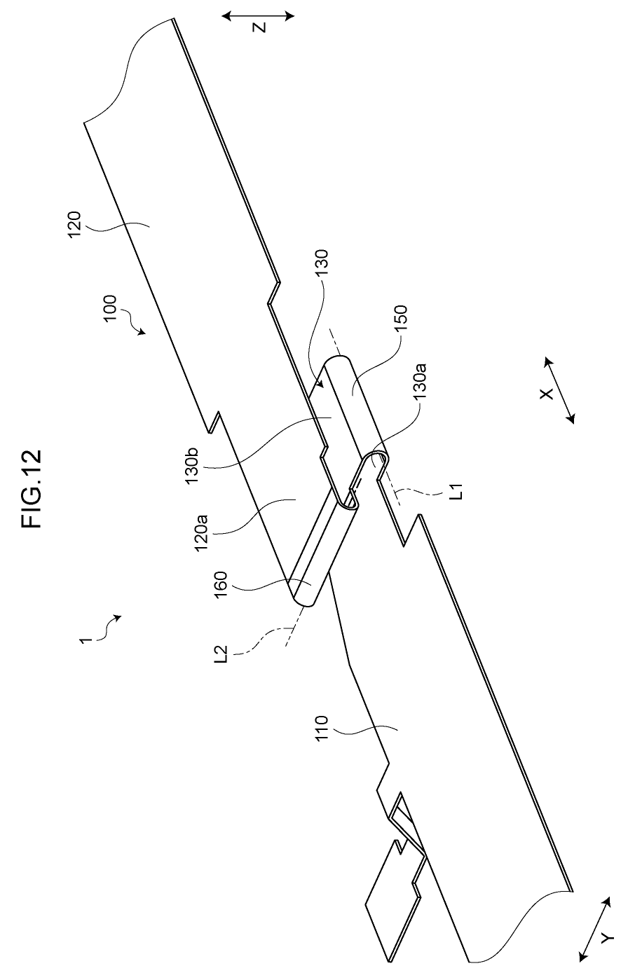

An embodiment will be described with reference to FIGS. 1 to 12. The present embodiment relates to a wire harness. FIGS. 1 and 2 are perspective views of a wire harness according to an embodiment, FIG. 3 is a plan view of a case according to the embodiment, FIG. 4 is a perspective view of the case according to the embodiment, FIG. 5 is a plan view of a flat wiring member according to the embodiment, FIG. 6 is a plan view of the wire harness according to the embodiment, FIGS. 7 to 9 are perspective views of the wire harness according to the embodiment, FIG. 10 is a diagram illustrating a second rotation process of the embodiment, FIG. 11 is a perspective view of the wire harness according to the embodiment, and FIG. 12 is a perspective view of the flat wiring member according to the embodiment.

As illustrated in FIG. 1, a wire harness 1 of the present embodiment includes a coupling portion 70 that couples two cases 10 and 20 to each other. As illustrated in FIG. 5, a flat wiring member 100 assembled to the two cases 10 and 20 has a substantially U shape in plan view. The flat wiring member 100 includes a first portion 110, a second portion 120, and an intermediate portion 130. The first portion 110 and the second portion 120 in plan view have substantially rectangular shapes. The flat wiring member 100 includes a slit 100s formed between the first portion 110 and the second portion 120.

The intermediate portion 130 connects an end of the first portion 110 having a straight line shape and an end of the second portion 120 having a straight line shape to each other. The intermediate portion 130 in plan view has a substantially trapezoidal shape. The intermediate portion 130 has a tapered shape whose width narrows as being farther away from the first portion 110 and the second portion 120 in the extending direction X. The extending direction X is a direction in which the first portion 110 extends and is a longitudinal direction of the first portion 110. In the flat wiring member 100 having an initial shape before transformation, the first portion 110 and the second portion 120 extend in the same extending direction X and are aligned in a width direction Y. The width direction Y is a direction orthogonal to the extending direction X, and is a width direction of the first portion 110 and the second portion 120.

The flat wiring member 100 of the present embodiment has a branch portion 170 connected to a busbar 200. The branch portion 170 extends in the width direction Y from the first portion 110 and the second portion 120. The distal end of the branch portion 170 is connected to the busbar 200 by solder, etc.

The flat wiring member 100 is, for example, a flexible printed circuit board (FPC). The flat wiring member 100 of the present embodiment is disposed in a battery module and detects the voltage and temperature of a battery cell of the battery module.

When the flat wiring member 100 is an FPC, the flat wiring member 100 includes a base film, a conductive layer, and a coverlay. The conductive layer is sandwiched and protected by the base film and the coverlay. The conductive layer is, for example, a conductive metal foil, and has a circuit pattern including a plurality of detection lines 140. The flat wiring member 100 has flexibility and can be bent to be wired.

Returning to FIG. 1, the coupling portion 70 of the present embodiment includes a hinge portion 72 configured to be able to rotate the two cases 10 and 20 relative to each other. The hinge portion 72 is deformable so as to rotate the two cases 10 and 20 relative to each other about an axis Cx as a rotation center. The hinge portion 72 can rotate the two cases 10 and 20 relative to each other to a relative position as illustrated in FIG. 2 in which the two cases 10 and 20 overlap with each other. The wire harness 1 of the present embodiment can improve the workability of the work of deforming the flat wiring member 100 formed in the U shape. In addition, the wire harness 1 of the present embodiment can reduce the load on the flat wiring member 100 when handling the cases 10 and 20.

FIGS. 3 and 4 illustrate the first case 10 and the second case 20 of the present embodiment. The first case 10 and the second case 20 are molded using an insulating synthetic resin, for example. The first case 10 includes a main body 11 and a cover 18. The main body 11 and the cover 18 are integrally molded, for example. In the first case 10 of the present embodiment, the main body 11 and the cover 18 are connected to each other via a hinge portion 11e. The main body 11 includes a first support wall 11a that supports the first portion 110 of the flat wiring member 100. The first support wall 11a is formed in a straight line shape in the extending direction X. The cover 18 includes a facing wall 18a that covers the first support wall 11a. The first portion 110 of the flat wiring member 100 is accommodated and held between the first support wall 11a and the facing wall 18a.

At an end of the main body 11 in the extending direction X, there are provided a first shaft support portion 19A and a second shaft support portion 19B. The first shaft support portion 19A rotatably supports a first rotation shaft 25A of the second case 20. The second shaft support portion 19B rotatably supports a second rotation shaft 25B of the second case 20.

The second case 20 according to the embodiment includes a main body 21, a cover 24, and a coupling portion 70. The main body 21, the cover 24, and the coupling portion 70 are integrally molded, for example. In the second case 20 of the present embodiment, the main body 21 and the cover 24 are connected to each other via a hinge portion 21e. The main body 21 includes a second support wall 21a that supports the second portion 120 of the flat wiring member 100. The second support wall 21a is formed in a straight line shape in the extending direction X. The cover 24 includes a facing wall 24a that covers the second support wall 21a. The second portion 120 of the flat wiring member 100 is accommodated and held between the second support wall 21a and the facing wall 24a.

At an end of the main body 21 in the extending direction X, there is provided a first rotation shaft 25A. More specifically, an arm protruding in the extending direction X is provided at the end of the main body 21. The first rotation shaft 25A protrudes from the arm in the width direction Y.

The coupling portion 70 is connected to an end of the cover 24 in the extending direction X. The coupling portion 70 protrudes in the width direction Y from the cover 24 toward the side opposite to the main body 21 side. The coupling portion 70 includes a main body 71, a hinge portion 72, and a second rotation shaft 25B. The main body 71 has a flat plate shape and is adjacent to the facing wall 24a in the width direction Y. The main body 71 has a rectangular shape in plan view. The hinge portion 72 connects the facing wall 24a and the main body 71 and extends in the extending direction X. The hinge portion 72 is formed to be thinner than the main body 71 and the facing wall 24a.

The main body 71 has a proximal end 71a and a distal end 71b which are ends in the extending direction X. The proximal end 71a is an end connected to the hinge portion 72. The distal end 71b protrudes in the extending direction X with respect to the facing wall 24a. The second rotation shaft 25B is disposed at the distal end 71b. The second rotation shaft 25B extends in the width direction Y so as to cross the distal end 71b. The end of the second rotation shaft 25B protrudes toward the width direction Y from the side surface of the distal end 71b. Both ends of the second rotation shaft 25B are supported by the second shaft support portion 19B.

In the wire harness 1 according to the embodiment, the two shaft support portions 19A and 19B of the first case 10 and the two rotation shafts 25A and 25B of the second case 20 constitute the rotating structure 60. The rotating structure 60 enables relative rotation of the two cases 10 and 20 as illustrated in FIG. 10.

As illustrated in FIG. 4, the first case 10 includes a first engagement portion 12, and the second case 20 includes a second engagement portion 22. The first engagement portion 12 is disposed at an end of the main body 11 in the extending direction X. The second engagement portion 22 is disposed at an end of the main body 21 in the extending direction X. The two engagement portions 12 and 22 are engaged with each other in a second relative position illustrated in FIG. 11.

FIG. 6 illustrates the flat wiring member 100 assembled to the first case 10 and the second case 20. The first case 10 and the second case 20 illustrated in FIGS. 3 and 6 are aligned in the width direction Y. In the present specification, regarding the first case 10 and the second case 20, a relative position in which the two cases 10 and 20 are aligned in the width direction Y is denoted as a first relative position. As illustrated in FIG. 3, when the two cases 10 and 20 are disposed in the first relative position, the first support wall 11a of the first case 10 and the second support wall 21a of the second case 20 are aligned in the width direction Y.

The first portion 110 of the flat wiring member 100 is accommodated in the main body 11 of the first case 10 and is supported by the first support wall 11a. A process of accommodating the first portion 110 in the first case 10 is executed by an operator, for example. The second portion 120 of the flat wiring member 100 is accommodated in the main body 21 of the second case 20 and is supported by the second support wall 21a. A process of accommodating the second portion 120 in the second case 20 is executed by an operator, for example. The two accommodating processes are executed in a state where the two cases 10 and 20 are held by a jig plate, for example.

When the flat wiring member 100 has been accommodated in the two cases 10 and 20, a closing process of closing the covers 18 and 24 is executed. In the closing process, the cover 18 of the first case 10 is assembled to the main body 11 while bending the hinge portion 11e so as to be engaged with the main body 11. In the closing process, the cover 24 of the second case 20 is assembled to the main body 21 while bending the hinge portion 21e so as to be engaged with the main body 21. The two closing processes are executed by an operator, for example. FIGS. 1 and 7 illustrate states where the covers 18 and 24 are closed. The facing wall 18a of the cover 18 covers the first portion 110 of the flat wiring member 100. The facing wall 24a of the cover 24 covers the second portion 120 of the flat wiring member 100.

As illustrated in FIG. 7, when the cover 24 is closed and engaged with the main body 21, the coupling portion 70 is coupled to the first case 10. As illustrated in FIG. 7, the second shaft support portion 19B includes a slit 19f provided in a side wall 11h. The side walls 11h are disposed on both sides in the width direction Y with respect to the first support wall 11a. The end of the second rotation shaft 25B is inserted into the slit 19f and rotatably supported by the side wall 11h. By inserting both ends of the second rotation shaft 25B into the slits 19f, the coupling portion 70 is coupled to the first case 10.

In the state illustrated in FIG. 7, a first rotation process of rotating the second case 20 relative to the first case 10 is executed. In the first rotation process, the second case 20 is rotated relative to the first case 10 about the axis Cx illustrated in FIG. 1 as a rotation center. The axis Cx is a straight line in the extending direction X along the hinge portion 72. As illustrated in FIG. 7, the main body 71 of the coupling portion 70 is supported by the cover 18 of the first case 10. Therefore, the coupling portion 70 can bend the hinge portion 72 in a state where the main body 71 is supported, and can rotate the second case 20 relative to the first case 10.

The wire harness 1 of the present embodiment improves workability in the first rotation process. The coupling portion 70 stabilizes a rotation center when the two cases 10 and 20 rotate relative to each other. In the wire harness 1 of the present embodiment, the first case 10 and the second case 20 are coupled to each other via the coupling portion 70. The coupling structure by the coupling portion 70 can restrict relative movable directions and relative movable ranges of the two cases 10 and 20. For example, the coupling portion 70 can suppress damage to the flat wiring member 100 due to excessive separation between the two cases 10 and 20 in the first rotation process. Therefore, the wire harness 1 of the present embodiment can reduce the load on the flat wiring member 100 when handling the two cases 10 and 20.

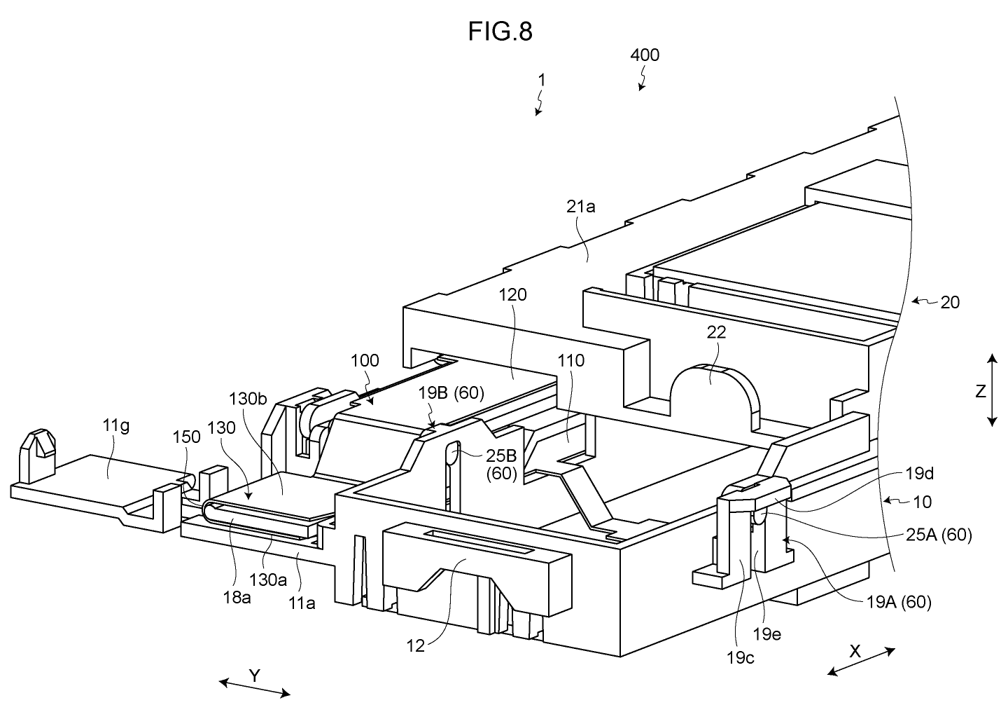

FIG. 8 illustrates two cases 10 and 20 which are overlapped with each other after the first rotation process is completed. When the two cases 10 and 20 overlap with each other in a height direction Z, the first portion 110 and the second portion 120 of the flat wiring member 100 face each other in the height direction Z. In the present specification, a relative position in which the first portion 110 and the second portion 120 of the flat wiring member 100 face each other in the height direction Z is denoted as a facing position regarding the first case 10 and the second case 20. When the two cases 10 and 20 are positioned in the facing position, the first support wall 11a and the second support wall 21a face each other in the height direction Z.

By the first rotation process, a first folded portion 150 is formed in the flat wiring member 100. At the first folded portion 150, the intermediate portion 130 is folded along a folding line L1 (refer to FIG. 12) extending in the extending direction X. The folding line L1 is a straight line extending in the extending direction X between the two covers 18 and 24, for example. The intermediate portion 130 includes: a first region 130a connected to the first portion 110; and a second region 130b connected to the second portion 120. The intermediate portion 130 is folded back such that the first region 130a and the second region 130b face each other in the height direction Z.

In the first rotation process, the first rotation shaft 25A of the second case 20 is engaged with the first shaft support portion 19A of the first case 10. As illustrated in FIG. 8, the first shaft support portion 19A includes: a piece portion 19c erected in the height direction Z; and a locking portion 19d. The piece portion 19c has a slit 19e extending in the height direction Z. The end of the first rotation shaft 25A is inserted into the slit 19e and locked by the locking portion 19d. By the engagement of the first rotation shaft 25A with the first shaft support portion 19A, the two cases 10 and 20 are coupled in overlapping states. This constitutes a busbar module 400. The busbar module 400 includes a plurality of busbars 200 and the wire harness 1 of the embodiment.

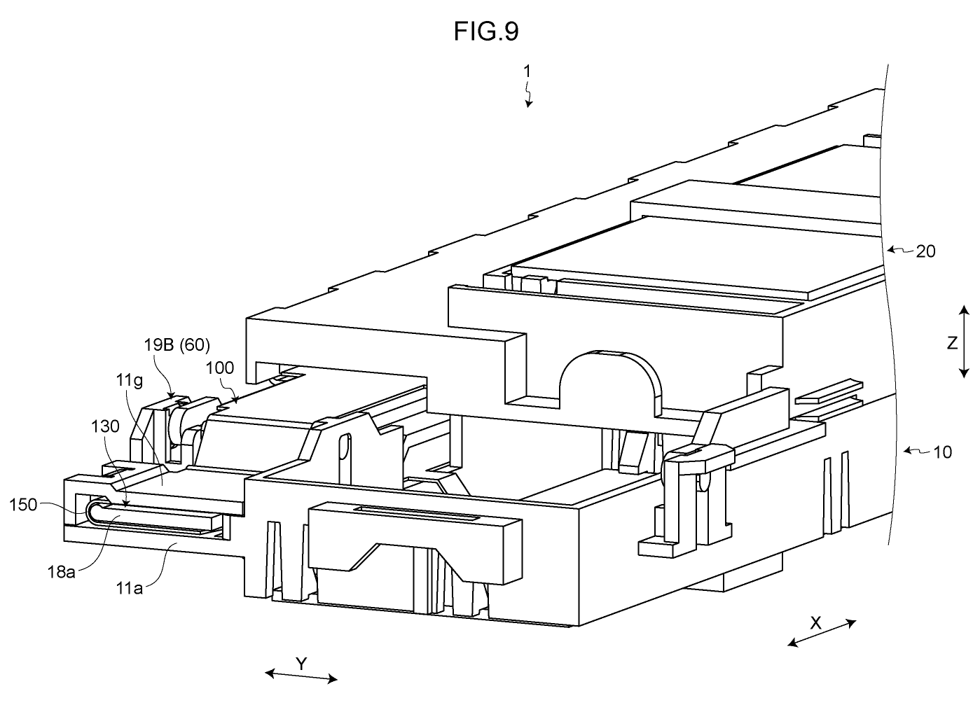

When the two cases 10 and 20 are overlapped with each other, the intermediate portion 130 is protected by a protective cover 11g as illustrated in FIG. 9. The protective cover 11g is connected to the first support wall 11a via the hinge portion, and is configured to engage with the main body 11 so as to cover the intermediate portion 130. The first case 10 accommodates the intermediate portion 130 folded back in a U shape between the first support wall 11a and the protective cover 11g. The facing wall 18a of the cover 18 is sandwiched inside the folded intermediate portion 130.

For example, the wire harness 1 is conveyed in a state where the two cases 10 and 20 overlap each other and the intermediate portion 130 is covered with the protective cover 11g. The two cases 10 and 20 overlap each other so as to sandwich the flat wiring member 100, and thus can protect the flat wiring member 100 at the time of conveyance. In addition, the protective cover 11g covers the intermediate portion 130 and thus can suppress interference of peripheral components with the intermediate portion 130.

The rotating structure 60 of the present embodiment is configured to be able to rotate the two cases 10 and 20 relative to each other from the facing position in FIGS. 8 and 9 to the second relative position in FIG. 11. As illustrated in FIG. 8, the first rotation shaft 25A and the second rotation shaft 25B are rotatably supported by the first case 10 in the facing position. Accordingly, the second case 20 can rotate relative to the first case 10 about the center axis of the two rotation shafts 25A and 25B as a rotation center.

In the wire harness 1 of the present embodiment, the shape of the flat wiring member 100 can be deformed into a straight line shape by the second rotation process described below. FIG. 10 is a diagram illustrating the second rotation process. The second rotation process is executed in a factory in which the busbar module 400 is assembled to a vehicle, etc., for example. As illustrated in FIG. 10, in the second rotation process, the second case 20 is rotated relative to the first case 10 from the facing position toward a second relative position to be described below. In the second rotation process, the second case 20 rotates relative to the first case 10 about the center axis of the two rotation shafts 25A and 25B as a rotation center. As can be seen from FIG. 8, the first engagement portion 12 of the first case 10 is disposed at a position engageable with the second engagement portion 22 of the second case 20. That is, the first engagement portion 12 is disposed on a track of the second engagement portion 22 when the second case 20 rotates relative to the first case 10.

FIG. 11 illustrates a state where the second rotation process is completed and the two cases 10 and 20 are positioned in the second relative position. In the second relative position, the first case 10 and the second case 20 are aligned in a straight line shape along the extending direction X. In addition, the first support wall 11a and the second support wall 21a are aligned in a straight line shape along the extending direction X. Accordingly, the first portion 110 and the second portion 120 of the flat wiring member 100 are aligned in a straight line shape. In other words, the second portion 120 is positioned on an extension line of the first portion 110 in plan view. In addition, the plurality of busbars 200 are aligned in a straight line shape along the extending direction X. The cover 18 of the first case 10 covers the first portion 110 by the facing wall 18a to protect the first portion 110. The cover 24 of the second case 20 covers the second portion 120 by the facing wall 24a to protect the second portion 120.

The second rotation process is executed to form a second folded portion 160 in the flat wiring member 100. As illustrated in FIG. 12, the second folded portion 160 is a portion folded along a folding line L2 orthogonal to the extending direction X. In the second folded portion 160, the second portion 120 is folded along the folding line L2 such that a part of the second portion 120 overlaps with the intermediate portion 130. The folding line L2 of the present embodiment is a straight line extending in the width direction Y. When the second folded portion 160 is formed, the second region 130b of the intermediate portion 130 and a proximal end 120a of the second portion 120 face each other. The proximal end 120a is an end of the second portion 120 on a side close to the intermediate portion 130.

The two cases 10 and 20 can engage with each other in a state where the flat wiring member 100 has a straight line shape. The first engagement portion 12 and the second engagement portion 22 engage with each other to position the two cases 10 and 20 in the second relative position. In the wire harness 1 of the present embodiment, the U-shaped flat wiring member 100 can be deformed into a straight line shape and wired to a target object.

As described above, the wire harness 1 of the present embodiment includes the flat wiring member 100, the first case 10, the second case 20, and the coupling portion 70. The flat wiring member 100 is formed in a U shape including the first portion 110 having a straight line shape, the second portion 120 having a straight line shape, and the intermediate portion 130 connecting the first portion 110 and the second portion 120. The first case 10 holds the first portion 110, and the second case 20 holds the second portion 120. The coupling portion 70 couples the first case 10 and the second case 20 to each other.

The first case 10 includes the first support wall 11a that supports the first portion 110. The second case 20 includes the second support wall 21a that supports the second portion 120. The coupling portion 70 is configured to couple the first case 10 and the second case 20 to each other in a state where the first support wall 11a and the second support wall 21a are aligned along the width direction Y of the flat wiring member 100. The coupling portion 70 includes the hinge portion 72. The hinge portion 72 can rotate the first case 10 and the second case 20 relative to each other to make the first support wall 11a and the second support wall 21a face each other. According to the wire harness 1 of the present embodiment, by coupling the two cases 10 and 20 to each other by the coupling portion 70, the load on the flat wiring member 100 when handling the cases 10 and 20 can be reduced.

The second case 20 of the present embodiment includes: the main body 21 having the second support wall 21a; and the cover 24 that engages with the main body 21 and covers the second support wall 21a. The coupling portion 70 is connected to the cover 24, and is coupled to the first case 10 in a state where the cover 24 is engaged with the main body 21. With this configuration, the process of closing the cover 24 and the process of coupling the two cases 10 and 20 to each other become a series of processes, improving the workability.

The wire harness 1 of the present embodiment has the rotating structure 60 that couples the first case 10 and the second case 20 to each other so as to be able to rotate relative to each other. The rotating structure 60 couples the first case 10 and the second case 20 to each other in a state where the first case 10 and the second case 20 are overlapped with each other in a state where the first support wall 11a and the second support wall 21a face each other. The rotating structure 60 is configured to rotate the first case 10 and the second case 20 relative to each other such that the first support wall 11a and the second support wall 21a are aligned in a straight line shape. In the wire harness 1 of the present embodiment, two rotation processes of transforming the flat wiring member 100 can be executed in a state where the first case 10 and the second case 20 are coupled to each other. This reduces the load on the flat wiring member 100 when handling the cases 10 and 20.

Note that the shape of the flat wiring member 100 at a time of wiring to the target object is not limited to the straight line shape. For example, the flat wiring member 100 may be wired, in the U shape illustrated in FIG. 5, to the target object. In this case, the wire harness 1 may be conveyed to a factory where the wiring process is performed in a state where the two cases 10 and 20 are positioned in the facing position as illustrated in FIG. 9.

Alternatively, the flat wiring member 100 may be wired to the target object in a state where the two cases 10 and 20 are positioned in the facing position. In these cases, the first case 10 and the second case 20 need not include the rotating structure 60.

The contents disclosed in the above embodiment can be executed in appropriate combination with each other.

The wire harness according to the embodiment includes the coupling portion that couples the first case and the second case to each other, and the coupling portion includes a hinge portion capable of making the first case and the second case rotate relative to each other such that a first support wall and the second support wall face each other. According to the wire harness of the embodiment, there is an effect that the load on the flat wiring member when handling the first case and the second case can be reduced.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wire harness comprising:
a flat wiring member formed in a U shape, the flat wiring member including a first portion having a straight line shape, a second portion having a straight line shape, and an intermediate portion connecting an end of the first portion and an end of the second portion;
a first case that holds the first portion;
a second case that holds the second portion; and
a coupling portion that couples the first case and the second case to each other, wherein
the first case includes a first support wall that supports the first portion,
the second case includes a second support wall that supports the second portion,
the coupling portion is configured to couple the first case and the second case to each other in a state where the first support wall and the second support wall are aligned in a width direction of the flat wiring member, and
the coupling portion includes a hinge portion capable of rotating the first case and the second case relative to each other to make the first support wall and the second support wall face each other.

2. The wire harness according to claim 1, wherein
the second case includes: a main body having the second support wall; and a cover that engages with the main body and covers the second support wall, and
the coupling portion is connected to the cover, and is coupled to the first case in a state where the cover is engaged with the main body.

3. The wire harness according to claim 2, further comprising:
a rotating structure that couples the first case and the second case to each other so as to be rotatable relative to each other, wherein
the rotating structure couples the first case and the second case to each other in a state where the first case and the second case are overlapped with each other with the first support wall and the second support wall facing each other, and
the rotating structure is configured to be able to rotate the first case and the second case relative to each other such that the first support wall and the second support wall are aligned in a straight line shape.
